(19) United States
(12) Patent Application Publication
(10) Pub. No.: US 2012/0247817 A1
(43) Pub. Date: Oct. 4, 2012

(54) CONDUCTIVE PARTICLES, CONDUCTIVE PASTE, AND CIRCUIT BOARD

(75) Inventors: Hayato Hommura, Kanagawa (JP); Go Sudo, Kanagawa (JP); Kenji Katori, Kanagawa (JP)

(73) Assignee: SONY CORPORATION, Tokyo (JP)

(21) Appl. No.: 13/422,873

(22) Filed: Mar. 16, 2012

(30) Foreign Application Priority Data
Mar. 30, 2011 (JP) 2011-074408

(51) Int. Cl. H05K 1/09; H01B 1/02; B82Y 30/00

(52) U.S. Cl. 174/257; 252/514; 977/755

(57) ABSTRACT

Conductive particles include silver particles and at least one coating material which is selected from silver alloys and silver composites and which covers the silver particles.

### CROSS REFERENCES TO RELATED APPLICATIONS

The present application claims priority to Japanese Priority Patent Application JP 2011-074408 filed in the Japan Patent Office on Mar. 30, 2011, the entire content of which is hereby incorporated by reference.

### BACKGROUND

The present application relates to conductive particles including metal particles, the surfaces of which are coated with a conductive coating material, a conductive paste containing the conductive particles, and a circuit board fabricated using the conductive paste.

Printable electronics using printing techniques have been receiving attention as a fabrication process of electronic devices. Printable electronics are used in a wide range of applications, in which silver is used as an interconnect material in many cases from the standpoints of electroconductivity and oxidation resistance. Examples of use of silver include conductive pastes obtained by dispersing silver particles, together with a binder, in an organic solvent, and paints obtained by dispersing nano-silver particles, the surfaces of which are protected by an organic material, in an organic solvent.

Furthermore, instead of silver, copper particles and silver-coated copper particles which have been silver-plated are used. For example, refer to Japanese Unexamined Patent Application Publication No. 9-92026.

### SUMMARY

However, in any of conductive pastes including silver particles or silver-coated copper particles, migration (electrochemical migration) easily occurs because of the presence of silver. Migration is a phenomenon in which a metal in an interconnect line on the higher potential side is ionized, ions which have moved to an interconnect line on the lower potential side are reduced to precipitate the metal, and the precipitate grows into dendrites and reaches the interconnect line on the higher potential side, thus causing short-circuiting between the interconnect lines. The migration tends to occur in the case where there is a potential difference between interconnect lines and water or water vapor is present or in the case where a circuit board has moisture absorption.

Furthermore, when copper particles are used, because of the fact that copper is easily oxidized, in interconnect lines coated with the paste, it is difficult to reduce resistivity as low as silver.

It is desirable to provide conductive particles having excellent conductivity and migration resistance, a conductive paste including the conductive particles, and a circuit board.

According to an embodiment of the present application, there is provided conductive particles including silver particles and at least one coating material which is selected from silver alloys and silver composites and which covers the silver particles.

According to another embodiment of the present application, there is provided a conductive paste including the conductive particles and a binder resin.

According to another embodiment of the present application, there is provided a circuit board including a substrate and a circuit disposed on the substrate, the circuit being formed of the conductive paste.

In the conductive particles according to the embodiment of the present application, by coating silver particles having high conductivity with a coating material composed of a silver alloy or silver composite containing silver having high conductivity, high conductivity is exhibited. Furthermore, by coating the surface of silver in which migration easily occurs with a silver alloy or silver composite, it is possible to suppress occurrence of migration. By using a conductive paste containing the conductive particles, it is possible to fabricate a circuit board provided with a circuit having high conductivity and excellent migration resistance.

According to the embodiments of the present application, it is possible to provide conductive particles having excellent conductivity and migration resistance, a conductive paste including the conductive particles, and a circuit board.

Additional features and advantages are described herein, and will be apparent from the following Detailed Description and the figures.

### BRIEF DESCRIPTION OF THE FIGURES

FIG. 1 is a cross-sectional view showing a structure of a production apparatus for producing conductive particles according to an embodiment of the present application;

FIG. 2 is a view for illustrating a circuit board according to an embodiment of the present application; and

FIG. 3 is a view for illustrating a circuit board according to an embodiment of the present application.

### DETAILED DESCRIPTION

The examples of embodiments of the present application will be described below. However, it is to be understood that the present application is not limited to the examples. The description will be made in the following order:

1. Structure of conductive particles according to an embodiment
2. Conductive paste according to an embodiment
3. Circuit board according to an embodiment

### 4. Examples

### 1. STRUCTURE OF CONDUCTIVE PARTICLES ACCORDING TO AN EMBODIMENT

A specific embodiment of conductive particles will be described below.

### [Structure of Conductive Particles]

Conductive particles according to this embodiment have silver particles as cores, and the surfaces of the silver particles are coated with a coating material composed of a silver alloy or silver composite. By coating the surfaces of silver particles, in which migration easily occurs, with a silver alloy or silver composite having excellent migration resistance and high conductivity, in the resulting conductive particles, it is possible to suppress occurrence of migration while maintaining high conductivity.

Silver particles in the conductive particles according to this embodiment will be described. The silver particles preferably have a high silver purity in view of conductivity, and in general, it is possible to use silver having the same purity as that of silver bullion used for the electronics industry or the like. Furthermore, a metal other than silver, an impurity, or the like may be incorporated to such an extent that it does not degrade conductivity and it does not change characteristics of silver.

The shape of the silver particles is not particularly limited and may be spherical, flaky, angular, or the like. Furthermore, silver particles having the same shape and size may be used, or two or more kinds of silver particles having different shapes and sizes may be used. In the case where two or more kinds of silver particles are mixed for use, it is necessary to dispose a coating material on the surface of each of the particles.

In the case where conductive particles are used as an interconnect material, preferably, flaky silver particles and spherical silver particles are mixed for use. Flaky particles have a large specific surface area and it is possible to increase the contact area between conductive particles during formation of interconnect lines. Thereby, it is possible to decrease the resistivity of the interconnect lines. When flaky particles only are mixed with a resin binder to produce a conductive paste, it is difficult to adjust the viscosity and the like, and the application properties of the conductive paste are degraded. For this reason, spherical particles are mixed with the flaky particles so as to obtain suitable application properties of the conductive particles.

Preferably, the silver particles have an average particle size of 0.3 to 15 μm. In the case where a conductive paste is produced using particles with a small particle size, in comparison with the case where large particles are used, the surface area of particles increases, and in order to ensure adhesion of coating films, it may be necessary to increase the ratio of a resin binder. Consequently, when the particle size is less than 0.3 μm, the ratio of a resin binder to be mixed may increase, resulting in a decrease in conductivity, which is undesirable. On the other hand, when the particle size is more than 15 μm, problems, such as clogging and stringiness of the conductive paste, may occur in the interconnect line formation process, which is undesirable.

Next, the coating material of the conductive particles will be described. As the coating material, a material having high migration resistance and low resistivity is used. As such a material, a silver alloy or silver composite which contains silver and at least one element added to silver is used. Since the coating material contains silver, it is possible to reduce resistivity. Furthermore, by using a silver alloy or silver composite in which at least one element is added to silver, it is possible to suppress migration of silver.

The element to be added to silver is not particularly limited as long as the resulting silver alloy or silver composite has low resistivity and can suppress migration of silver. Furthermore, a plurality of elements may be combined so as to form a silver alloy or silver composite having good resistivity and migration resistance.

As the element to be added to silver, for example, at least one element selected from the group consisting of Pd, Cu, Al, Bi, rare earth elements, Au, Pt, Ti, Zr, Hf, Rh, and Ir can be used.

As the coating material, preferably, a silver alloy or silver composite, such as AgBi or AgPdAuHf, is used. In particular, use of Ag₍₁₋ₓ₎Biₓ (where the expression 0.005≦x≦0.02 is satisfied) or Ag_{(1-x-y-z)}PdₓAu_{y}Hf_{z} (where the expressions 0.03≦x≦0.10, 0.02≦y≦0.07, and 0.03≦z≦0.08 are satisfied) is preferable.

Furthermore, as the coating material, for example, a silver alloy or silver composite generally used as a reflecting film in an optical recording medium is suitable.

In the conductive particles, regarding the coverage of the coating material on the surfaces of silver particles, a higher coverage is preferable in view of suppression of migration, and in particular, a coverage of 100% is preferable. Accordingly, the thickness of the coating material of the conductive particles is set so that a sufficient coverage can be ensured. Preferably, the thickness that can ensure sufficient coverage is, for example, 10 to 300 nm, and in particular, 20 to 200 nm. When the thickness of the coating material of the conductive particles is less than 10 nm, the coatability of the coating material at the surfaces of silver particles is low, and it is difficult to sufficiently suppress migration of silver particles. On the other hand, when the thickness of the coating material of the conductive particles is more than 300 nm, the electroconductivity of the conductive particles decreases, which is undesirable.

The coating material is formed on silver particles, for example, by a physical vapor deposition method in which the silver alloy or silver composite is used as a target or evaporation source. Specific examples of the physical vapor deposition method include sputtering, vapor deposition, and laser ablation. The method is not particularly limited as long as the surfaces of silver particles are satisfactorily coated. In the case where flaky silver particles are coated by the physical vapor deposition method, coatability may differ depending on the shape of the surface of the particles. Therefore, the range of the thickness of the coating material described above is the average of all the silver particles. The average can be calculated from the surface area of silver particles and the amount of coating material used in physical vapor deposition.

### [Production Method for Conductive Particles]

In a production method for conductive particles, as an example of a process of forming a coating material on the surfaces of silver particles, sputtering will be described. In this process, sputtering is performed using a silver alloy or silver composite target in which at least one element is added to silver.

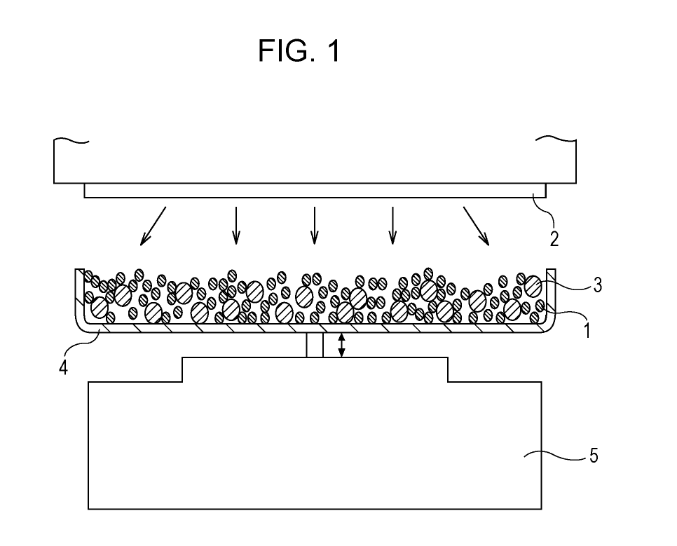

FIG. 1 is a cross-sectional view of a production apparatus used for producing conductive particles. In the production apparatus shown in FIG. 1, silver particles 1 are placed in a container 4 having a substantially planar bottom, and sputtering is performed. Balls 3 with smooth surfaces are mixed with the silver particles 1 in the container 4. The container 4 is provided on a vibrating device 5 which includes a magnetic coil or ultrasonic horn. By operating the vibrating device 5 and applying vibration to the container 4, the upper surface of the container 4, in which the silver particles 1 and the balls 3 are placed, serves as a vibrating surface. The production apparatus shown in FIG. 1 is provided with a target 2 which faces the upper surface of the container 4 in which the silver particles 1 are placed. The target 2 is the silver alloy or silver composite described above.

A process in which, using the production apparatus shown in FIG. 1, the surfaces of the silver particles 1 are coated with the silver alloy or silver composite by the physical vapor deposition method will be described below.

First, the container 4 in which the silver particles 1 and the balls 3 are placed is fixed in a vacuum chamber and a vacuum state is produced. Then, the vibrating device 5 is operated to apply vibration to the container 4, thereby producing a state in which the silver particles 1 and the balls 3 are fluidized. In this process, by using the balls 3 having smooth surfaces together with the silver particles 1, the balls 3 can be made to act as a vibration amplifier. While maintaining this state, sputtering is performed using the silver alloy or silver composite as the target 2.

By using the apparatus described above, the silver particles 1 are fluidized while being mixed with the balls 3, and do not remain at one spot in the container 4. Therefore, by the sputtering, all of the silver particles 1 in the container 4 can be uniformly coated with the silver alloy or silver composite.

In the conductive particles according to the embodiment described above, since the surfaces of silver particles are coated with the silver alloy or silver composite, the silver particles which are cores of the conductive particles are protected by the silver alloy or silver composite. Accordingly, occurrence of migration due to silver is suppressed. Furthermore, by using, as the coating material, the silver alloy or silver composite in which another element is added to silver, it is possible to prevent reduction in electroconductivity due to the coating material.

### 2. CONDUCTIVE PASTE ACCORDING TO AN EMBODIMENT

### [Conductive Paste]

A conductive paste according to this embodiment in which the conductive particles described above are used will be described below. The conductive paste includes the conductive particles which include the silver particles and a coating material composed of a silver alloy or silver composite which covers the surfaces of the silver particles, and a resin binder in which the conductive particles are dispersed.

As the resin binder used in the conductive paste, an organic resin generally used in a silver paste, a solder paste, or the like can be used. For example, as the resin binder, a polyester resin, an acrylic resin, a polyurethane resin, an epoxy resin, or the like can be used. Furthermore, the type of the organic resin used as the binder resin is not particularly limited, and resins other than those described above may be used in the conductive paste.

Furthermore, preferably, a curing agent that reacts with the organic resin is incorporated into the conductive paste. Although the type of the curing agent is not particularly limited, use of an isocyanate, an acid anhydride, an amino resin, or the like is preferable. Furthermore, in order to promote the curing reaction between the binder resin and the curing agent, a suitable catalyst or accelerator may be used together.

In order to adjust the application properties of the conductive paste, the viscosity or the like may be adjusted using a solvent. The type of the solvent is not limited, and an ester-based solvent, a ketone-based solvent, an alcohol-based solvent, a hydrocarbon-based solvent, an ether-based solvent, or the like may be used. These may be used alone or two or more may be used in combination.

As necessary, a leveling agent, an anti-foaming agent, a dispersing agent, and the like may be added to the conductive paste.

In the conductive paste, the composition ratio between the conductive particles and the binder resin can be set in any range depending on the particle size, shape, and the like of the silver particles and a resin composition used as the binder resin. Furthermore, the composition range of the conductive paste can be appropriately changed depending on the object to which the conductive paste is applied, the process used, or the like.

For example, in the case where conductive particles having an average particle size of 9 μm and a specific surface area of 0.4 m²/g are used, the solid content ratio of the conductive particles to the binder resin (parts by mass) is preferably in the range of 96:4 to 85:15. When the binder resin content is less than the range described above, adhesion with the substrate and integrity of the coating film formed of the conductive paste decrease, resulting in failure in functioning as an electrode, which is undesirable. When the binder resin content is more than the range described above, the volume resistivity after being heat-cured increases, which is undesirable.

### 3. CIRCUIT BOARD ACCORDING TO AN EMBODIMENT

A circuit board according to this embodiment fabricated using the conductive paste described above will be described below. In the circuit board according to this embodiment, a circuit is formed on a substrate using the conductive paste containing the conductive particles. By using the conductive particles, which includes silver particles and a coating material, as a printing material applied to a substrate or the like, occurrence of migration can be suppressed and a circuit board with low resistance can be achieved.

As the substrate used in the circuit board, it is possible to use a material generally used in manufacturing circuit boards, to which the conductive paste can be applied and which is not thermally decomposed or melted at a temperature equal to or lower than the heat-curing temperature of the conductive paste. Examples thereof that can be used include resin films, such as polyethylene terephthalate films, polyimide films, and polyamide-imide films, paper phenolic laminates, epoxy resin glass fabric base laminates, polyimide resin glass fabric base laminates, glass substrates, quartz substrates, and silicon wafers.

The circuit board is produced by a method in which using the conductive paste described above, a circuit is formed on a substrate. Any publicly known method of producing a circuit board using a conductive paste can be used without particular limitation. For example, the circuit board can be produced by applying the conductive paste to the substrate using an ink jet method, screen printing method, or the like.

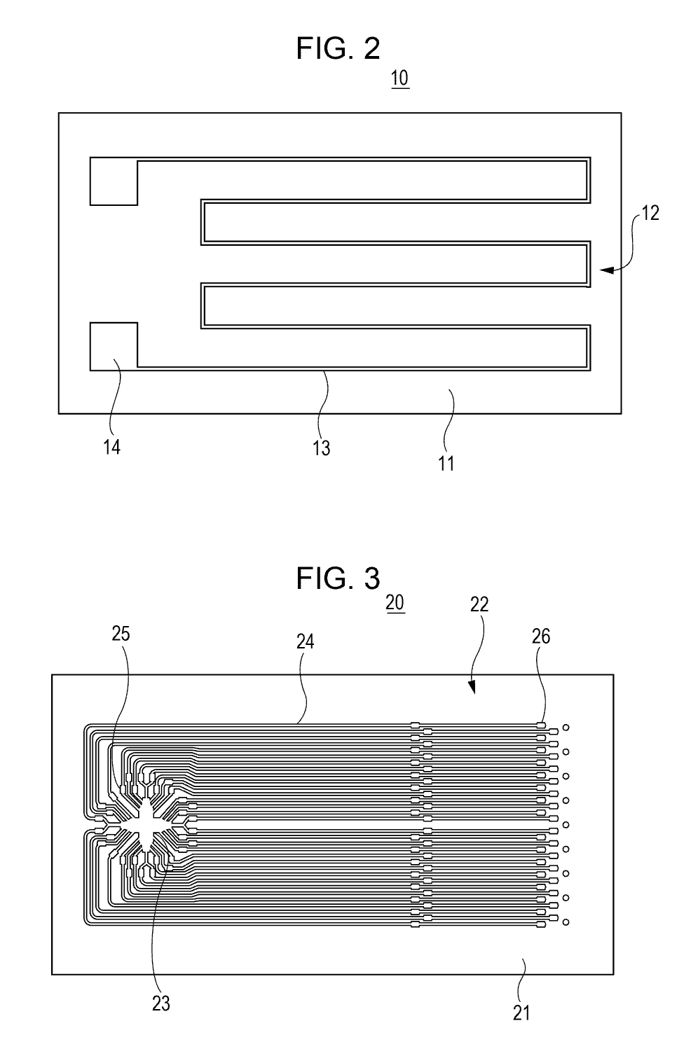

FIGS. 2 and 3 each show an example of a circuit board according to this embodiment. In a circuit board 10 shown in FIG. 2, a circuit 12 is disposed on a film-like substrate 11, such as a flexible substrate. For example, the circuit 12 composed of the conductive paste containing conductive particles is formed on the film-like substrate 11 composed of a polyethylene terephthalate film or the like. The circuit 12 includes electrode portions 14 for connection to an external device and an interconnect line portion 13 which connects the electrode portions 14 to each other and which has a plurality of bends.

A circuit board 20 shown in FIG. 3 has a circuit 22 for mounting elements, such as semiconductor chips. For example, the circuit 22 composed of the conductive paste containing conductive particles is formed on a substrate 21 composed of an epoxy resin glass fabric base laminate or the like. The circuit 22 has a chip mounting portion 23 including electrode portions 25 corresponding to an external electrode pattern of elements to be mounted on the circuit board 20. Furthermore, the circuit 22 includes the electrode portions 25 constituting the chip mounting portion 23, electrode portions 26 for connection to external devices, and interconnect line portions 24 for connecting the electrode portions 25 and the electrode portions 26.

The volume resistivity of the circuit formed on the circuit board using the conductive paste is preferably 1×10⁻³ Ωcm or less, and in particular, 1×10⁻⁴ Ωcm or less. By decreasing the volume resistivity, the circuit can cope with interconnect miniaturization and can be applied to relatively long interconnect lines, such as planar coil-shaped lines.

### 4. EXAMPLES

Embodiment of the present application will be specifically described below on the basis of examples.

### Example 1

### (Conductive Particles)

In conductive particles used in Example 1, as silver particles, commercially available silver particles (average particle size: 9 μm, specific surface area: 0.4 m²/g, manufactured by Fukuda Metal Foil & Powder Co., Ltd.) were used. Furthermore, bismuth-doped silver (Ag₉₉Bi₁) was used as a sputtering target material as a source of a coating material.

The silver particles were coated with the silver alloy by sputtering as a physical vapor deposition method. Sputtering was performed so that the thickness of the coating material on the surfaces of silver particles was 20 nm to form conductive particles.

### (Conductive Paste)

Using the conductive particles described above, a conductive paste was produced. First, 95 parts by mass of the conductive particles, 4.8 parts by mass (in terms of solid content) of a polyester resin (UE3210, manufactured by Unitika Ltd.), 0.2 parts by mass (in terms of solid content) of blocked isocyanate, and 0.02 parts by mass of dibutyltin dilaurate as a curing catalyst were mixed. Then, an appropriate amount of diluted solvent was added to the mixture, and thorough mixing was performed using a ball mill until the mixture became homogeneous. Thereby, a conductive paste of Example 1 was produced.

### Example 2

A conductive paste of Example 2 was produced as in Example 1 except that sputtering was performed so that the thickness of the coating material on the surfaces of silver particles was 50 nm to form conductive particles.

### Example 3

A conductive paste of Example 3 was produced as in Example 1 except that sputtering was performed so that the thickness of the coating material on the surfaces of silver particles was 100 nm to form conductive particles.

### Example 4

A conductive paste of Example 4 was produced as in Example 1 except that sputtering was performed so that the thickness of the coating material on the surfaces of silver particles was 200 nm to form conductive particles.

### Example 5

A conductive paste of Example 5 was produced as in Example 1 except that sputtering was performed so that the thickness of the coating material on the surfaces of silver particles was 300 nm to form conductive particles.

### Comparative Example

A conductive paste of Comparative Example was produced as in Example 1 except that silver particles not coated with a coating material are used as conductive particles of Comparative Example.

### (Evaluation Method: Migration Resistance)

Using the conductive paste of each of Examples 1 to 5 and Comparative Example, a comb-shaped electrode with a line width of 2 mm, a line pitch of 2 mm, and a parallel portion length of 50 mm was printed on an annealed polyester film with a thickness of 100 μm. After printing, heat-curing was performed at 150° C. for 30 minutes to produce a circuit board of each of Examples 1 to 5 and Comparative Example.

A glass fiber filter (GF/A, manufactured by Whatman Ltd.) was placed on the circuit-formed surface of the circuit board (lower electrode) of each of Examples 1 to 5 and Comparative Example, and the glass fiber filter was moistened by dropping distilled water. Furthermore, another circuit board (upper electrode) of each of Examples 1 to 5 and Comparative Example was placed on the glass fiber so as to face the circuit board serving as the lower electrode.

The migration resistance was determined by a method in which a direct voltage of 10 V was applied between the opposing circuit boards (upper electrode and lower electrode), the value of current flowing between comb-shaped electrodes was measured, and the time until the current value reached 2 mA was measured. A longer time indicates that the circuit board has higher migration resistance.

### (Evaluation Method: Volume Resistivity)

The volume resistivity was measured by a four probe method. The conductive paste of each of Examples 1 to 5 and Comparative Example was printed on a substrate, and heat-curing was performed at 150° C. for 30 minutes to produce a circuit board of each of Examples 1 to 5 and Comparative Example. The sheet resistance of the circuit board of each of Examples 1 to 5 and Comparative Example was measured by the four probe method, and the volume resistivity was calculated from the resulting sheet resistance and the thickness of the circuit.

The evaluation results of migration resistance and volume resistivity in Examples 1 to 5 and Comparative Example are shown in Table below.

TABLE

| | | | | | | Compar- |
|---|---|---|---|---|---|---|
| | Exam- | Exam- | Exam- | Exam- | Exam- | ative |
| | ple 1 | ple 2 | ple 3 | ple 4 | ple 5 | Example |
| Coating | 20 nm | 50 nm | 100 nm | 200 nm | 300 nm | No |
| material | | | | | | coating |
| layer | | | | | | material |
| Migration/ | 250 | 560 | 740 | 1040 | 1280 | 65 |
| sec | | | | | | |
| Volume | 5.0 × | 6.5 × | 8.5 × | 1.3 × | 2.0 × | 3.5 × |
| resistivity/ | 10⁻⁵ | 10⁻⁵ | 10⁻⁵ | 10⁻⁴ | 10⁻⁴ | 10⁻⁵ |
| Ωcm | | | | | | |

As shown in Table, the circuit board using conductive particles having a thicker coating material layer has higher migration resistance. As is clear from this result, by forming a coating material on silver particles, the migration resistance can be significantly improved. In particular, while the migration resistance is 65 seconds in the specimen of Comparative Example in which a coating material is not provided, the migration resistance is 250 seconds in the specimen having a coating material layer with a smallest thickness of 20 nm. There is a significant difference between the two specimens. Accordingly, regarding the migration resistance, by forming a coating material layer with a thickness of 20 nm on silver particles, a sufficient effect is obtained. Because of this difference, it is believed that even if the thickness of the coating material layer of conductive particles is smaller than 20 nm, for example, about 10 nm which is the minimum thickness at which coatability is secured, a sufficient effect can be obtained in terms of migration resistance.

Furthermore, as shown in Table, although the volume resistivity is slightly increased by the coating treatment, in the specimen having a largest thickness of the coating material layer of 300 nm, the volume resistivity is 1×10⁻³ Ωcm or less. In the region less than 200 nm, the volume resistivity is low at on the order of 1×10⁻⁴ Ωcm or less. This shows that even when the surfaces of silver particles are coated with a coating material having excellent migration resistance, it is possible to maintain high conductivity.

As is clear from the results of the examples described above, by using the conductive particles according to the embodiment and the conductive paste including the conductive particles as a printing material, it is possible to produce a circuit board which has high conductivity and which can suppress occurrence of migration. Consequently, unlike the existing interconnect lines using silver particles, in order to prevent occurrence of migration, it is not necessary to employ a method in which the silver line pitch is increased or in which the applied silver lines are overcoated with a carbon paste or the like. As a result of this, it is possible to prevent the fabrication process of circuit boards and electronic devices from being complicated, and it is possible to easily deal with finer pitches.

According to other embodiments of the present disclosure, there are provided the followings:

(1) Conductive particles including silver particles and at least one coating material which is selected from silver alloys and silver composites and which covers the silver particles.

(2) The conductive particles according to (1), wherein the coating material is an alloy or composite including silver and at least one element selected from the group consisting of Pd, Cu, Al, Bi, rare earth elements, Au, Pt, Ti, Zr, Hf, Rh, and Ir.

(3) The conductive particles according to (1) or (2), wherein the coating material is AgBi or AgPdAuHf.

(4) The conductive particles according to any one of (1) to (3), wherein the thickness of the coating material is 10 to 200 nm.

(5) A conductive paste including the conductive particles according to any one of (1) to (4) and a binder resin.

(6) The conductive paste according to (5), further including a curing agent which reacts with the binder resin.

(7) A circuit board including a substrate and a circuit disposed on the substrate, the circuit being formed of the conductive paste according to (5) or (6).

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

1. Conductive particles comprising:
silver particles; and
at least one coating material which is selected from silver alloys and silver composites and which covers the silver particles.

2. The conductive particles according to claim 1, wherein the coating material is an alloy or composite including silver and at least one element selected from the group consisting of Pd, Cu, Al, Bi, rare earth elements, Au, Pt, Ti, Zr, Hf, Rh, and Ir.

3. The conductive particles according to claim 1, wherein the coating material is AgBi or AgPdAuHf.

4. The conductive particles according to claim 1, wherein the thickness of the coating material is 10 to 200 nm.

5. A conductive paste comprising:
conductive particles including silver particles and at least one coating material which is selected from silver alloys and silver composites and which covers the silver particles; and
a binder resin.

6. The conductive paste according to claim 5, further comprising a curing agent which reacts with the binder resin.

7. A circuit board comprising:
a substrate; and
a circuit disposed on the substrate, the circuit being formed of a conductive paste containing conductive particles including silver particles and at least one coating material which is selected from silver alloys and silver composites and which covers the silver particles, and a binder resin.
